(19) United States
(12) Patent Application Publication
(10) Pub. No.: US 2023/0335368 A1
(43) Pub. Date: Oct. 19, 2023

(54) ELECTROMAGNETIC LENS AND ELECTRON SOURCE MECHANISM

(71) Applicant: NuFlare Technology, Inc., Yokohama-shi (JP)

(72) Inventors: Munehiro OGASAWARA, Hiratsuka-shi (JP); Atsushi ANDO, Edogawa-ku (JP); Kazuhiko INOUE, Yokohama-shi (JP)

(73) Assignee: NuFlare Technology, Inc., Yokohama-shi (JP)

(21) Appl. No.: 18/170,142

(22) Filed: Feb. 16, 2023

(30) Foreign Application Priority Data
Apr. 19, 2022 (JP) 2022-068771

(51) Int. Cl. H01J 37/141; H01J 37/147; H01J 37/065

(52) U.S. Cl. CPC H01J 37/141; H01J 37/1475; H01J 37/065

(57) ABSTRACT

An electromagnetic lens includes a coil, and a pole piece configured to include an upper wall, a lower wall, an outer peripheral wall and an inner peripheral wall which are formed using a conductive magnetic material, to surround the coil by the upper wall, the lower wall, the outer peripheral wall and the inner peripheral wall, one of opposite facing surfaces of an upper part and a lower part of the inner peripheral wall and opposite facing surfaces of the upper wall and the inner peripheral wall being insulated electrically, the outer peripheral wall including a laminated structure where a magnetic material and an insulator are alternately laminated in a direction of a central axis of a trajectory of a passing electron beam, and to be covered at least the laminated structure of the outer peripheral wall with an insulator.

### CROSS-REFERENCE TO RELATED APPLICATION

This application is based upon and claims the benefit of priority from prior Japanese Patent Application No. 2022-068771 filed on Apr. 19, 2022 in Japan, the entire contents of which are incorporated herein by reference.

### BACKGROUND OF THE INVENTION

### Field of the Invention

Embodiments of the present invention relate to an electromagnetic lens and an electron source mechanism, and, for example, relate to an electromagnetic lens for applying a lens effect on electron beams used by an apparatus that irradiates a target object with the electron beams, and to an electron source mechanism in which the electromagnetic lens is installed.

### Description of Related Art

As an apparatus for irradiating a target object with electron beams, there are, for example, a pattern inspection apparatus for inspecting defects of ultrafine patterns exposed/transferred onto a semiconductor wafer, a writing apparatus for writing a pattern on a mask which is used when exposing/transferring an ultrafine pattern onto a semiconductor wafer by using a photolithography technique, and the like. With respect to such apparatuses, it is examined to irradiate a target substrate with multiple electron beams, for example. Multiple beams are formed by one electron beam, emitted from an electron source, irradiating an aperture array, for example. The electron beam here means a set of one or more electrons travelling in the same direction on almost the same trajectory. The multiple beams here mean a set of a plurality of different electron beams travelling on close trajectories. However, even in the case of a single beam, its thickness changes according to cases. Similarly, the distance between electron beams configuring multiple beams, and the size of the entire multiple beams also change according to cases. Hereinafter, an electron beam is sometimes referred to as just a beam.

When taking out beams from an electron source, an electrostatic lens is arranged in the acceleration space in the electron source in order to converge electron beams by the lens effect while accelerating electrons emitted from the cathode, and to make them emit from the electron source. Generating electron beams from a plurality of electrons emitted out of the cathode is hereinafter expressed as emitting beams from the cathode. There is a requirement to take out electron beams of high brightness and large current from the electron source, such as a thermal field emission (TFE) electron gun, in order to generate large current multiple beams composed of electron beams of high brightness. For increasing taken currents, not only beams with a small divergence angle but also beams with a large one need to be used in the beams emitted from the cathode. However, beams with a large divergence angle has a problem that if they are converged by an electrostatic lens, an aberration becomes large. In order to prevent the aberration, it is desirable to apply a lens effect of an electromagnetic lens to beams in the acceleration space. However, if a pole piece (also called a yoke) of the electromagnetic lens is close to the acceleration space in the electron source, a new problem occurs that the electric field in the acceleration space is largely disturbed.

There is disclosed a configuration where the lower side end of the gap of a pole piece is connected, through an insulator, to the extraction electrode (e.g., refer to Japanese Patent Application Laid-open (JP-A) No. 2000-003689). However, in that configuration, although an electric discharge may not occur under a low potential difference whose absolute value is low, it may occur with a high possibility under a high potential difference such as −10 kV order.

### BRIEF SUMMARY OF THE INVENTION

According to one aspect of the present invention, an electromagnetic lens includes a coil, and a pole piece configured to include an upper wall, a lower wall, an outer peripheral wall and an inner peripheral wall which are formed using a conductive magnetic material, to surround the coil by the upper wall, the lower wall, the outer peripheral wall and the inner peripheral wall, one of opposite facing surfaces of an upper part and a lower part of the inner peripheral wall and opposite facing surfaces of the upper wall and the inner peripheral wall being insulated electrically, the outer peripheral wall including a laminated structure where a magnetic material and an insulator are alternately laminated in a direction of a central axis of a trajectory of a passing electron beam, and to be covered at least the laminated structure of the outer peripheral wall with an insulator.

According to another aspect of the present invention, an electron source mechanism includes the electromagnetic lens described above, and an electron source configured to be disposed, where an electron beam acceleration space to which a lens action is applied is arranged so as to be surrounded by the electromagnetic lens, emit an electron beam, and accelerate the electron beam in a space surrounded by the electromagnetic lens.

### BRIEF DESCRIPTION OF THE DRAWINGS

FIG. 1 is a sectional view showing an example of a configuration of an electron source mechanism according to a first embodiment;

FIG. 2 is an illustration showing an example of an electron gun according to a comparative example 1 of the first embodiment;

FIG. 3 is an illustration showing an example of an electron gun according to a comparative example 2 of the first embodiment;

FIG. 4 is an illustration showing an example of an electron source mechanism in which an electromagnetic lens is disposed according to the comparative example 2 of the first embodiment;

FIG. 5 is an illustration showing an example of an analytic model for calculating an allowable thickness of an insulator of a laminated structure of a pole piece according to the first embodiment;

FIG. 6 is a graph showing an example of a magnetic field distribution formed using an analytic model according to the first embodiment;

FIG. 7 is a graph showing a relationship between a ratio of a leakage magnetic field and the width of a space in an analytic model according to the first embodiment;

FIG. 8 is a sectional view showing an example of a configuration of an electron source mechanism according to a modified example of the first embodiment;

FIG. 9 is a sectional view showing an example of a configuration of an electron source mechanism according to another modified example of the first embodiment;

FIG. 10 is an illustration showing an example of a separation mechanism of an electromagnetic lens according to the first embodiment;

FIG. 11 is a sectional view showing an example of a configuration of an electron source mechanism according to another modified example of the first embodiment;

FIG. 12 is a sectional view showing an example of a configuration of an electron source mechanism according to another modified example of the first embodiment;

FIG. 13 is a diagram showing a configuration of an inspection apparatus according to the first embodiment;

FIG. 14 is a conceptual diagram showing a configuration of a shaping aperture array substrate according to the first embodiment;

FIG. 15 is an illustration showing an example of a plurality of chip regions formed on a semiconductor substrate, according to the first embodiment;

FIG. 16 is an illustration describing inspection processing according to the first embodiment;

FIG. 17 is a diagram showing an example of an internal configuration of a comparison circuit according to the first embodiment;

FIG. 18 is a sectional view showing an example of a configuration of an electron source mechanism according to a second embodiment;

FIG. 19 is an illustration for explaining an example of a separation mechanism of an electromagnetic lens according to the second embodiment;

FIG. 20 is a sectional view showing an example of a configuration of an electron source mechanism according to a third embodiment;

FIG. 21 is a sectional view showing an example of a configuration of an electron source mechanism according to a fourth embodiment; and

FIG. 22 is a sectional view showing an example of a configuration of an electron source mechanism according to a fifth embodiment

### DETAILED DESCRIPTION OF THE INVENTION

The embodiments bellow provide an electromagnetic lens and electron source mechanism in which the pole piece can be arranged close to an electric field space of a high potential difference whose absolute value is high while suppressing an electric field disturbance.

The embodiments below describe an inspection apparatus using multiple electron beams as an example of an electron beam irradiation apparatus. However, it is not limited thereto. The inspection apparatus may use a single electron beam. Further, it is not limited to the inspection apparatus. For example, it may be a writing apparatus using a single electron beam or multiple electron beams. Further, as an electron source, a thermal field emission (TFE) electron gun will be described. However, it is not limited thereto. An electron gun of another mechanism may be used. In the embodiments below, a magnetic material indicates a ferromagnetic material.

### First Embodiment

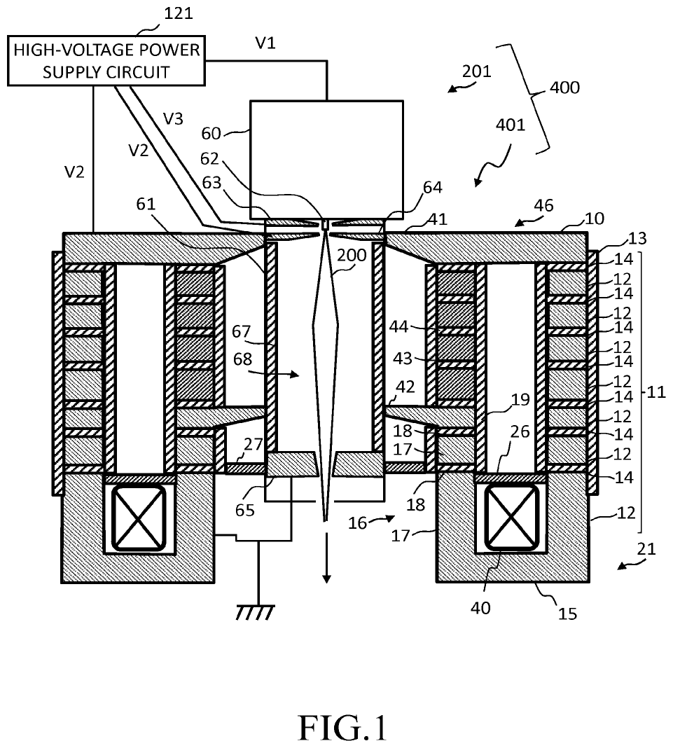

FIG. 1 is a sectional view showing an example of a configuration of an electron source mechanism according to a first embodiment. In FIG. 1, an electron source mechanism 400 of the first embodiment includes an electron gun 201 and an electromagnetic lens 401. An electron beam acceleration space to which a lens action is applied in the electron gun 201 (electron source) is arranged so as to be surrounded by the electromagnetic lens 401. The space where the electron source mechanism 400 is disposed is in an airtight container (not shown) evacuated by a vacuum pump (not shown). The electron source mechanism 400 is placed under high vacuum.

The electron gun 201 includes an electron gun head 60, an electron optical column 61, a cathode (electric field emitter tip) 62, a suppressor 63, an extractor (extraction electrode) 64, and an anode electrode 65. The cathode 62, the suppressor 63, the extractor 64, and the anode electrode 65 are disposed in the electron optical column 61. The inner wall of the optical column 61 is covered with an insulator 67. The distance between the extractor 64 and the anode electrode 65 is much longer than that between the suppressor 63 and the extractor 64.

As the cathode 62 (electric field emitter tip), it is preferable to use a ZrO/W emitter formed by a tungsten (W) <100> single crystal coated with zirconium dioxide (ZrO), for example. The cathode 62 is attached to a tungsten filament (not shown). The tungsten filament (not shown) is disposed in the electron gun head 60.

A conductive material is used as the material for the suppressor 63, the extractor 64, and the anode electrode 65. In the first embodiment, it is preferable to use a magnetic conductive material as the extractor 64 and the anode electrode 65. For example, they are formed with iron. Alternatively, the surface of a magnetic material may be coated with a conductive material.

The electromagnetic lens 401 includes a coil 40 and a pole piece (yoke) 46 which surrounds the coil 40. It is preferable to arrange the coil 40 as close to the anode electrode 65 side as possible in the space in the pole piece 46.

The pole piece 46 has an upper wall 10, a lower wall 15, an outer peripheral wall 11, and an inner peripheral wall 16 which are made of a magnetic material. The inner peripheral wall 16 surrounds the whole side surface of the optical column 61 of the electron gun 201. The outer peripheral wall 11 arranged outside the inner peripheral wall 16 surrounds the whole side surface of the optical column 61 and the inner peripheral wall 16. The upper wall 10 is arranged such that the upper side of the space between the outer peripheral wall 11 and the inner peripheral wall 16 is closed. The lower wall 15 is arranged such that the lower side of the space between the outer peripheral wall 11 and the inner peripheral wall 16 is closed. The coil 40 is surrounded by the upper wall 10, the lower wall 15, the outer peripheral wall 11, and the inner peripheral wall 16. As the magnetic material, a conductive magnetic material is used, and preferably is iron, for example.

According to the first embodiment, as shown in FIG. 1, the outer peripheral wall 11 has a laminated structure where a magnetic material 12 and an insulator 14 are alternately laminated in the direction of the central axis of the trajectory of a passing electron beam. In the case of FIG. 1, the inner peripheral wall 16 also has a laminated structure where a magnetic material 17 and an insulator 18 are alternately laminated in the direction of the central axis of the trajectory of the passing electron beam. The thickness of the insulator 14 (insulator 18) is formed to be thinner than that of the magnetic material 12 (magnetic material 17). The height position of each layer of the insulator 14 and that of each corresponding layer of the insulator 18 are formed to be the same as each other.

At least the laminated structure of the outer peripheral wall 11 is covered with the insulator 13. In other words, at least the outer peripheral surface and inner peripheral surface of the laminated structure portion of the outer peripheral wall 11 are covered with the insulator 13. Similarly, at least the outer peripheral surface and inner peripheral surface of the laminated structure portion of the inner peripheral wall 16 are covered with an insulator 19.

With respect to the pole piece 46, a coil surrounding part 21, which surrounds the inner peripheral side and the outer peripheral side of the coil 40, is formed by a magnetic material. The magnetic material 12 at the lower end of the outer peripheral wall 11, the lower wall 15, and the magnetic material 17 at the lower end of the inner peripheral wall 16 are preferably integrated in a body. In other words, the laminated structure of the outer peripheral wall 11 and that of the inner peripheral wall 16 are formed above the coil 40.

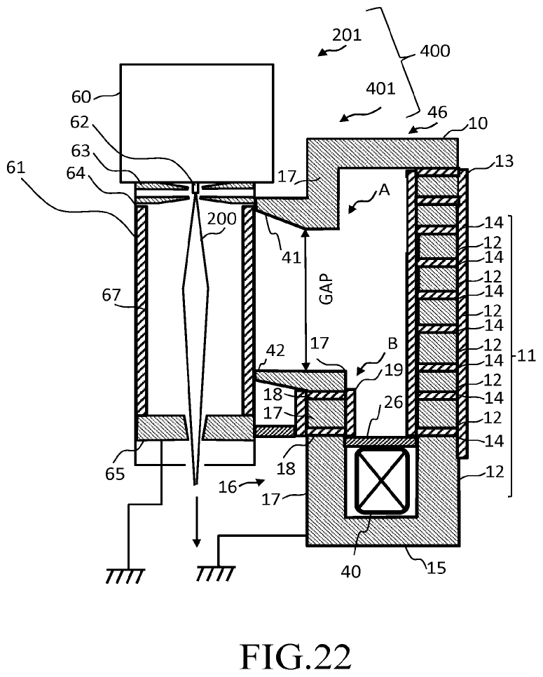

In the pole piece 46, a gap in which no magnetic material is disposed is formed at the inner peripheral side of the inner peripheral wall 16 so that a magnetic field may be emitted. The gap is formed between the opposite facing surfaces of the upper part and the lower part of the inner peripheral wall 16, or between the opposite facing surfaces of the upper wall 10 and the inner peripheral wall 16. In the example of FIG. 1, a gap is formed between the opposite facing surfaces of the upper wall 10 and the inner peripheral wall 16. In the case of FIG. 1, the counter surfaces forming the gap have flanges 41 and 42 which extend to the inner peripheral side. The flanges 41 and 42 are not needed to be covered with an insulator. The case where a gap is formed between the opposite facing surfaces of the upper part (part A) and the lower part (part B) configuring the inner peripheral wall 16 is shown in FIG. 22. In that case, the inner peripheral wall 16 of the pole piece 46 is divided into the upper part (part A) and the lower part (part B). Then, a gap for emitting a magnetic field is formed between the opposite facing surfaces of the upper part and the lower part configuring the inner peripheral wall 16.

In the example of FIG. 1, the flange 41 extending to the inner peripheral side than the inner peripheral wall 16 is formed at the upper wall 10. The flange 41 is integrated, using the same magnetic material, with the upper wall 10. In other words, the upper wall 10 has the flange 41 (first flange) which extends to the inner peripheral side than the inner peripheral wall 16.

In the example of FIG. 1, the flange 42 extending inner peripheral side than the inner peripheral wall 16 is formed at the upper end of the inner peripheral wall 16. In other words, the inner peripheral wall 16 has at its upper end the flange 42 (second flange) which extends to the inner peripheral side than other parts of the inner peripheral wall 16. The flange 42 is integrated, using the same magnetic material, with the inner peripheral wall 16.

In the example of FIG. 1, a laminated structure where a conductive non-magnetic material 43 and an insulator 44 are alternately laminated is formed at the position of the gap. It is preferable to use, for example, aluminum or titanium as the material of the non-magnetic material 43. The height position of each layer of the insulator 14 and that of each corresponding layer of the insulator 44 are formed to be the same as each other.

In the pole piece 46, the opposite facing surfaces of the upper part and the lower part of the inner peripheral wall 16, which form a gap, or the opposite facing surfaces of the upper wall 10 and the inner peripheral wall 16, which form a gap, are insulated electrically. In the case of FIG. 1, the insulator 44 is arranged between the opposite facing surfaces forming a gap. Further, the laminated structure portion where the non-magnetic material 43 and the insulator 44 are laminated alternately is covered with the insulator 19.

The end of the flange 42 being an inner peripheral side end of the upper part of the inner peripheral wall 16, or the end of the flange 41 being an inner peripheral side end of the upper wall 10 is electrically connected to the electrode (the extractor 64 or the anode electrode 65) of the electron gun 201 arranged surrounded by the electromagnetic lens 401. FIG. 1 shows the case where the end of the flange 41 is electrically connected to the extractor. The electrical connection includes the case of the flange 41 contacting the extractor 64, and the case of individually applying an electric potential V2 to the flange 41 and the extractor 64 from a high-voltage power supply circuit 121.

In the pole piece 46, the coil surrounding part 21 where the coil 40 is disposed is grounded. In other words, a ground potential is applied to the coil surrounding part 21. It is preferable that the upper part of the coil surrounding part 21 is closed by a conductive non-magnetic material 26. Thereby, the whole of the coil 40 can be sealed electrically, and protected from a high negative voltage.

The inner peripheral side end of the flange 42 is disposed on the side surface of the optical column 61 at a contact position or a non-contact position. The anode electrode 65 and the pole piece 46 are electrically connected through a conductive non-magnetic material 27. Although, in the case of FIG. 1, the non-magnetic material 27 is connected to the magnetic material 17 through the insulator 19 of the inner peripheral wall 16, it is not limited thereto. The non-magnetic material 27 may be placed in contact with the magnetic material 17. Thereby, in the pole piece 46, it becomes possible to prevent an electric potential difference between the coil surrounding part 21 and the anode electrode 65 from being generated.

The electron gun 201 is controlled by the high-voltage power supply circuit 121. The electron gun 201 accelerates an electron beam 200 in an acceleration space 68 surrounded by the electromagnetic lens 401 while emitting the electron beam 200. Specifically, it operates as follows:

The electron beam 200 is emitted from the cathode 62 when an acceleration voltage V1 (about −50 to −10 kV: −30 kV, for example) from the high-voltage power supply circuit 121 is applied to the cathode 62 through a filament in the electron gun head 60, and heated through the filament. The emitted electron beam 200 is extracted by the extractor 64 (extraction electrode) to which an electric potential V2 (about −45 to −5 kV: −25 kV, for example) from the high-voltage power supply circuit 121 has been applied, while its spreading is prevented by the suppressor 63 to which a bias potential V3 (about −50.3 to −10.3 kV: −30.3 kV, for example) from the high-voltage power supply circuit 121 has been applied. Then, the extracted electron beam 200 travels, in the acceleration space 68, toward the anode electrode 65 to which a ground potential (potential GND) has been applied.

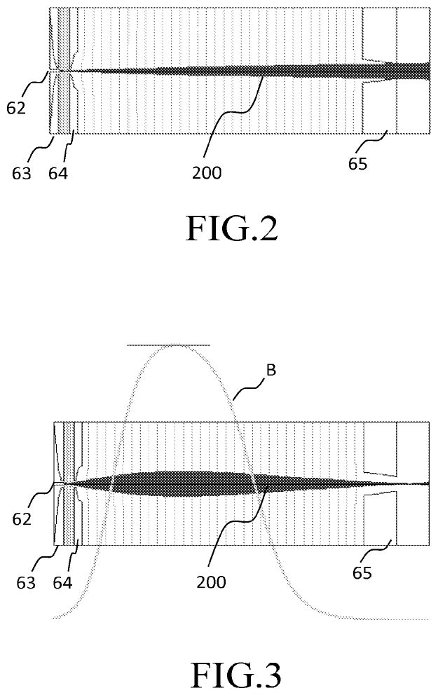

FIG. 2 is an illustration showing an example of an electron gun according to a comparative example 1 of the first embodiment. In the example of FIG. 2, illustrating an electron gun head is omitted. FIG. 2 shows an example of the case where a lens effect is not applied between the extractor 64 and the anode electrode 65. An electric field is formed between the extractor 64 and the anode electrode 65. The electron beam 200 extracted by extractor 64 travels, in the acceleration space 68, toward the anode electrode 65 to which a ground potential (potential GND) has been applied. At this process, the electron beam 200 travels while spreading. If the brightness is increased, the divergence angle of the beam close to the exit of the electron gun becomes large as shown in FIG. 2.

Therefore, it has been examined to arrange an electrostatic lens with a plurality of electrodes (not shown) in the acceleration space in the electron source, and to converge a beam by a lens effect while accelerating the beam emitted from the cathode in order to emit the converged beam from the electron gun. However, the divergence angle is too large when securing a desired large current. Thus, even if the electron beam 200 is converged with the electrostatic lens, the size of the beam diameter cannot be minimized sufficiently, since aberration becomes large. And consequently, the brightness decreases.

FIG. 3 is an illustration showing an example of an electron gun according to a comparative example 2 of the first embodiment. In the example of FIG. 3, illustrating an electron gun head is omitted. The example of FIG. 3 shows the case where a lens effect of a magnetic field B of an electromagnetic lens is applied to the acceleration space between the extractor 64 and the anode electrode 65. As shown in FIG. 3, the electron beam 200 is converged by applying the lens effect of the magnetic field B to the electron beam 200. Thereby, the electron beam 200 can be emitted from the electron gun in the state where the beam diameter has been made small. In the case of applying a lens effect of the magnetic field of an electromagnetic lens to the electron beam 200, even when the divergence angle is large, the size of the beam diameter can be decreased, since an aberration can be small. As a result, a desired brightness can be secured.

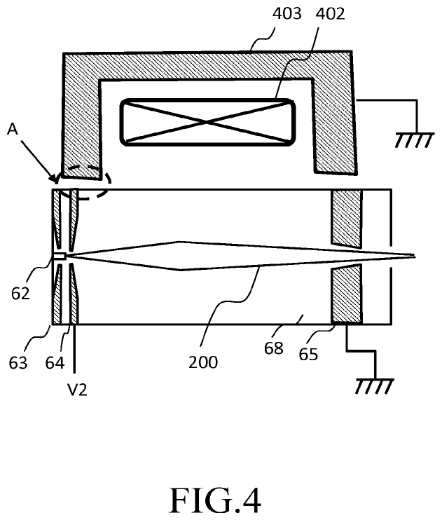

FIG. 4 is an illustration showing an example of an electron source mechanism in which an electromagnetic lens is disposed according to the comparative example 2 of the first embodiment. In the example of FIG. 4, illustrating an electron gun head is omitted. Further, in the sectional view of the electromagnetic lens, an illustration of the section of the opposite side across the electron gun is omitted. In the example of FIG. 4, a coil 402 is surrounded by a pole piece 403 of a magnetic material. The inner peripheral side of the pole piece 403 is open as a gap for emitting a magnetic field. By exciting the coil 402, a magnetic field can be generated in the acceleration space 68 of the electron gun. The electron beam 200 extracted by the extractor 64 travels, in the acceleration space 68, toward the anode electrode 65 to which a ground potential (potential GND) has been applied. In this process, the electron beam 200 receives a lens effect of a magnetic field, and travels, while converging, to the exit of the electron gun. A negative potential V2 (e.g., −25 kV) has been applied to the extractor 64. In contrast, in order not to put the coil 402 under a high voltage, the pole piece 403 is grounded (potential GND: 0 V). Therefore, if the pole piece 403 is brought close to the electron gun, a strong electric field is generated between the pole piece 403 and the extractor 64 (part A). An electric discharge may occur due to this strong electric field. When the pole piece 403 and the extractor 64 are in contact with each other, a short-circuiting phenomenon may occur. Even if an insulator is interposed in between at the inner peripheral side end of the pole piece 403, it is difficult to bear a high potential difference of 10-kV order though may be bearable against a low potential difference. Therefore, the electromagnetic lens needs to be far from the electron gun, thereby being substantially difficult to arrange the electromagnetic lens.

Then, according to the first embodiment, as shown in FIG. 1, the pole piece 46 is formed by a laminated structure of the magnetic material 12 (the magnetic material 17) and the insulator 14 (the insulator 18) from the anode electrode 65 side to the extractor 64 side. Thereby, when the pole piece 46 is arranged close to the electron gun 201, or the flanges 41 and 42 are arranged in contact with the electron gun 201, the electric potential of the pole piece 46 is divided at each height position of the pole piece 46 from the anode electrode 65 side to the extractor 64 side. By this, when the coil surrounding part 21 is grounded and the flange 41 of the upper wall 10 of the pole piece 46 has the same potential as that of the extractor 64, a plurality of stages of different potential portions can be formed between the coil surrounding part 21 and the upper wall 10 of the pole piece 46. Therefore, it becomes possible not to generate a strong electric field between the extractor 64 and the flange 41 of the upper wall 10 of the pole piece 46. Similarly, it becomes possible not to generate a potential difference between the anode electrode 65 and the non-magnetic material 27. Further, it becomes possible not to generate a strong electric field between the flange 42 of the inner peripheral wall 16 of the pole piece 46 and the acceleration space 68. Therefore, an electric discharge can be avoided. Further, a short circuit is avoidable even if contact occurs. Accordingly, an electric field disturbance in the acceleration space 68 can be avoided.

Then, the electromagnetic lens 401 generates, by exciting the coil 40, a lens magnetic field in the acceleration space 68 in the electron gun 201. Thereby, the electron beam 200 in the acceleration space 68 can be converged. Thus, the beam diameter close to the exit of the electron gun 201 can be reduced.

It is preferable to form the electrode (extractor 64) of the electron gun 201 by a magnetic material. Thereby, the extractor 64 is magnetically connected to the inner peripheral side end of the upper part of the inner peripheral wall 16, or the inner peripheral side end of the upper wall 10. In the example of FIG. 1, the extractor 64 is magnetically connected to the flange 41 being the inner peripheral side end of the upper wall 10. By connecting the extractor 64 magnetically, it can be operated as a magnetic field shield. The same applies to the case of forming the anode electrode 65 by a magnetic material. However, it is not limited thereto. The electrode (the suppressor 63, the extractor 64, and the anode electrode 65) of the electron gun 201 is only needed to be a conductive material, and may even be a non-magnetic material.

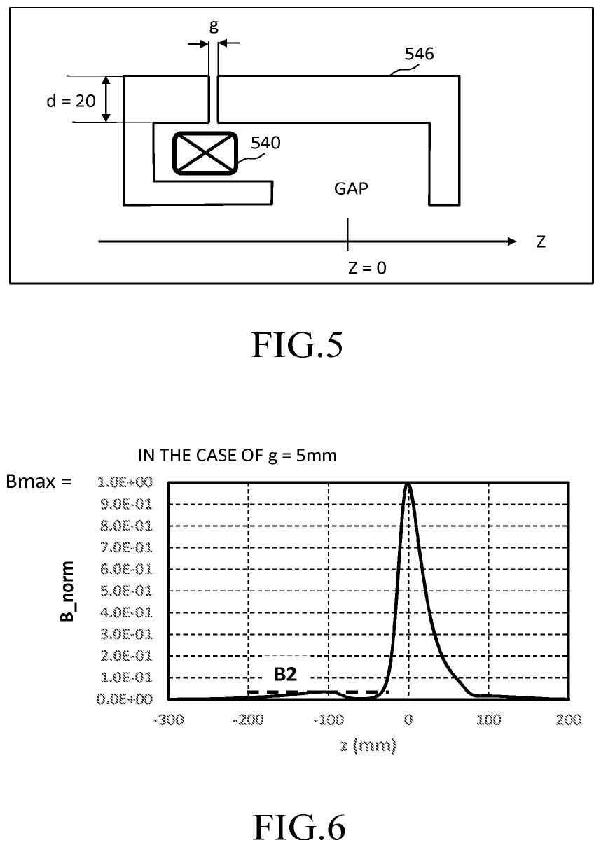

FIG. 5 is an illustration showing an example of an analytic model for calculating an allowable thickness of an insulator of a laminated structure of a pole piece according to the first embodiment. In FIG. 5, a coil 540 is disposed to be surrounded by a pole piece 546 of a magnetic material. A gap for emitting a magnetic field is open at the inner peripheral side of the pole piece 546. A space having a width g is formed in the outer peripheral wall having a thickness d of the pole piece 546. Under the condition that the thickness d of the outer peripheral wall of the pole piece 546 is fixed, while varying the width g of the space, a magnetic field distribution is measured which is formed using the model shown in FIG. 5.

FIG. 6 is a graph showing an example of a magnetic field distribution formed using an analytic model according to the first embodiment. In FIG. 6, the ordinate axis represents a magnetic field strength, and the abscissa axis represents a position Z. FIG. 6 shows an example of the magnetic field distribution generated when the coil 540 is excited using the analytic model shown in FIG. 5. The position of the maximum value Bmax of the magnetic field distribution is defined to be Z=0. For example, the position close to the center of the gap at the inner peripheral side of the pole piece 546 is equivalent to Z=0. As shown in the magnetic field distribution in FIG. 6, a small peak denoted by the strength B2 is generated in addition to a large peak of the maximum value Bmax. The small peak is attributed to a leakage magnetic field leaking from the space of the width g. FIG. 6 shows the case as an example where the thickness d of the outer peripheral wall of the pole piece 546 is d=20 mm, and the width g of the space is g=5 mm.

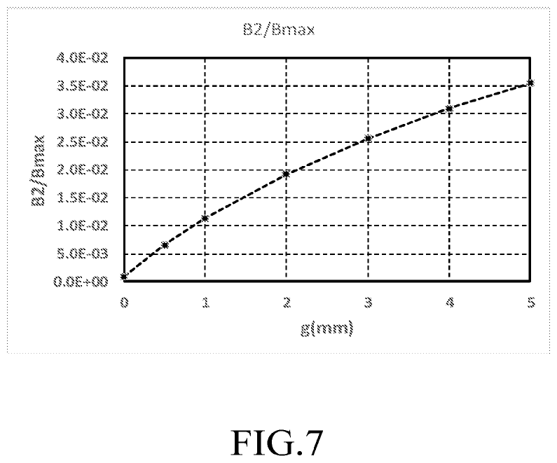

FIG. 7 is a graph showing a relationship between a ratio of a leakage magnetic field and the width of a space in an analytic model according to the first embodiment. In FIG. 7, the ordinate axis represents a ratio of the leakage magnetic field strength B2 to the maximum value Bmax of the magnetic field strength, (that is, B2/Bmax), and the abscissa axis represents the width g of the space. In the graph of FIG. 7, when d=20 mm, in order to make the strength B2 of the peak of the leakage magnetic field be 1/50 or less of the peak strength Bmax of the original magnetic field, it is necessary to be g=2 mm. This indicates that the peak strength B2 of the leakage magnetic field can be suppressed to 1/50 or less of the peak strength Bmax of the original magnetic field by making the aspect ratio d/g, obtained by dividing the thickness d of the outer peripheral wall of the pole piece 546 by the width g of the space, be more than 10. Therefore, according to the first embodiment, the width in the lamination direction of the insulator 14 (the insulator 18, the insulator 44) configuring the laminated structure of the pole piece 46 is formed such that the aspect ratio is equal to or greater than d/g=10. For example, the width (thickness) in the lamination direction of the insulator 14 (the insulator 18, the insulator 44) is formed to be about 0.5 to 2 mm.

Thus, according to the first embodiment, the laminated structure is formed using the insulator 14 whose width g (thickness) in the lamination direction is sufficiently small with respect to the thickness d of the outer peripheral wall of the pole piece 46. By interposing the insulator 14 (the insulator 18, the insulator 44) in between, the potential generated between magnetic materials 12 (the magnetic materials 17, the non-magnetic materials 43) at both sides is voltage-divided. In other word, by interposing the insulator 14 in between, the potential generated between the upper wall 10 and the magnetic material 12 located at the coil surrounding part 21 is voltage-divided. In this process, the potential difference generated between respective magnetic materials 12 (the magnetic materials 17, the non-magnetic materials 43) of the laminated structure can be reduced by increasing the number of times of lamination. FIG. 1 shows the case where the potential difference (e.g., 25 kV) between the extractor 64 and the anode electrode 65 is voltage-divided by dividing into eight magnetic layers. Thus, by interposing the insulator 14 (the insulator 18, the insulator 44) in between, the through discharge between the magnetic materials 12 (the magnetic materials 17, the non-magnetic materials 43) at both sides can be prevented. In other word, by interposing the insulator 14 in between, the through discharge between the upper wall 10 and the magnetic material 12 located at the coil surrounding part 21 can be prevented.

However, since the insulator 14 (the insulator 18, the insulator 44) having a thin thickness is used, a creeping discharge may occur. Then, according to the first embodiment, the creeping discharge can be prevented by further covering the laminated structure portion with the insulator 13 (insulator 19).

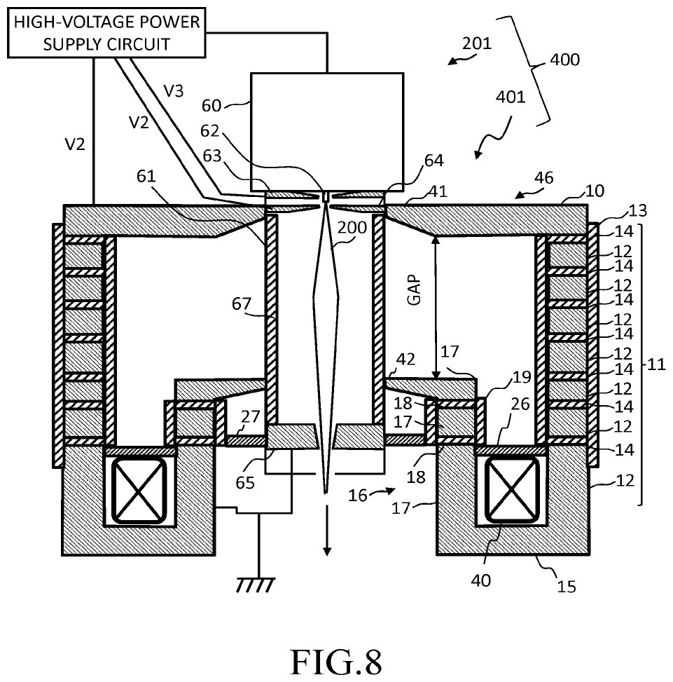

FIG. 8 is a sectional view showing an example of a configuration of an electron source mechanism according to a modified example of the first embodiment. FIG. 8 is the same as FIG. 1 except that the position of the gap for emitting a magnetic field is open instead of a non-magnetic material being disposed. As shown in FIG. 8, even when the gap is open without the non-magnetic material being disposed, the opposite both surfaces across the gap are insulated by the space. Thus, it is acceptable to make the gap open without arranging the non-magnetic material.

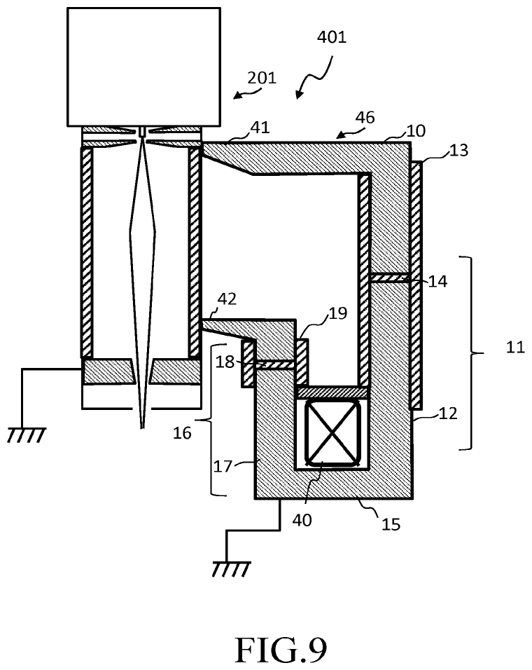

FIG. 9 is a sectional view showing an example of a configuration of an electron source mechanism according to another modified example of the first embodiment. In FIG. 9, in the sectional view of the electromagnetic lens 401, an illustration of the section of the opposite side across the electron gun 201 is omitted. FIG. 9 shows the case where the insulator 14 (the insulator 18) is interposed once in the laminated structure of the outer peripheral wall 11 (the inner peripheral wall 16). Thereby, the voltage can be divided once in the lamination direction of the pole piece 46. As shown in FIG. 9, the number of times of lamination of the insulator 14 (the insulator 18) may be once. In that case, since the potential difference between the magnetic materials 12 (the magnetic materials 17) at the both sides across the insulator 14 (the insulator 18) becomes large, a potential difference that can be withstood becomes smaller. For example, it is limited to less than 20 kV. Even when a through discharge is allowable, risk of generation of a creeping discharge increases. Then, as shown in FIG. 9, the creeping discharge can be prevented by covering the laminated structure portion with the insulator 13 (the insulator 19) which is at the center of the insulator 14 (the insulator 18) and in the lamination direction and whose length is sufficiently long with respect to the thickness of the insulator 14 (the insulator 18). Although the height positions in the lamination direction of the insulators 14 and 18 are different from each other in the example of FIG. 9, it is sufficient that the height position of the insulator 18 at the inner peripheral wall 16 which easily influences the electric field of the acceleration space 68 is about flush to the upper surface of the anode electrode 65. The other configuration is the same as that of FIG. 1.

Here, in order to degas the electron gun 201, it is necessary to perform baking before using. In contrast, in the electromagnetic lens 401, it is common that resin material, such as epoxy, is used for the coil 40, and when baking is performed, gas is emitted.

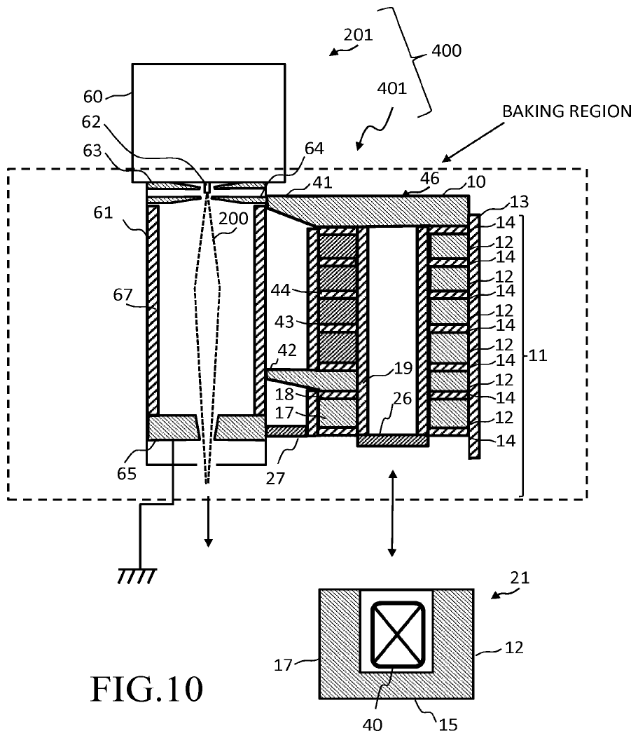

FIG. 10 is an illustration showing an example of a separation mechanism of an electromagnetic lens according to the first embodiment. As shown in FIG. 10, in the electromagnetic lens 401 of the first embodiment, the coil surrounding part 21 of the pole piece 46 is detachable. Thereby, when performing baking, the coil surrounding part 21 can be detached to move the coil 40 and its peripheral portions outwards from the baking region. It is preferable that the coil side end in the interior space interposed between the outer peripheral wall 11 and the inner peripheral wall 16 of the pole piece 46 is maintained closed by the non-magnetic material 26.

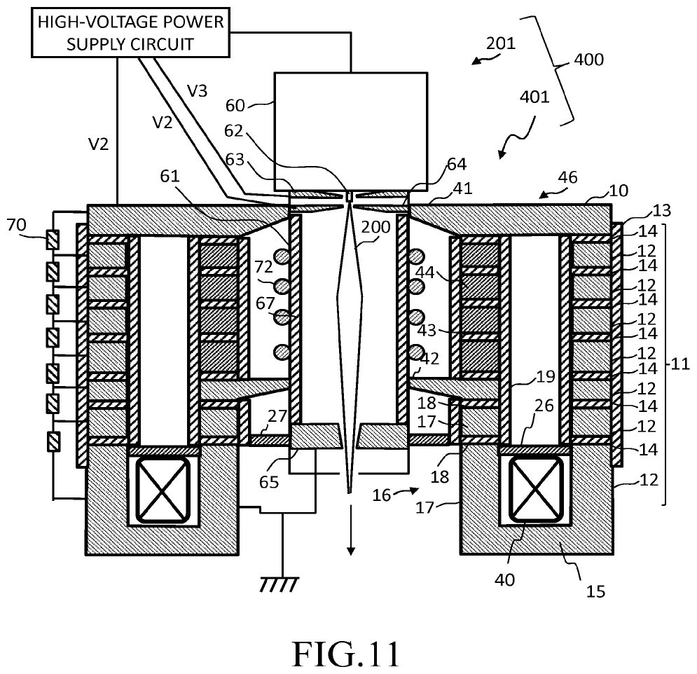

FIG. 11 is a sectional view showing an example of a configuration of an electron source mechanism according to another modified example of the first embodiment. FIG. 11 is the same as FIG. 1 except that at least one voltage dividing resistance 70 is arranged between adjacent magnetic materials 12 in the laminated structure. Respective adjacent magnetic materials 12 of the laminated structure of the outer peripheral wall 11 of the pole piece 46 are connected to each other by the voltage dividing resistance 70. Specifically, each voltage dividing resistance 70 is connected in series, and one end of the series is connected to the upper wall 10 which is equipotential to the extractor 64 and the other end is connected to the magnetic material 12 which is grounded. The wire between adjacent voltage dividing resistances 70 is connected to the layer of the corresponding magnetic material 12. Thereby, the electric potential of each magnetic material 12 can be ascertained. As the voltage dividing resistance 70, preferably, a resistance with a value of about 1 MΩ to 50 MΩ per stage is used, for example. In this process, in order to suppress the influence on the trajectory of electron beams of the magnetic field by the current flowing in the through voltage dividing resistance, it is desirable to arrange the voltage dividing resistance in plural rows such as eight rows, not in a single row.

In FIG. 11, it is also preferable to arrange a plurality of metal rings 72 around the optical column 61, with the voltage dividing resistance 70 or instead of the voltage dividing resistance 70. By arranging the plurality of metal rings 72 at a predetermined interval, even when a disturbance of an electric field distribution occurs, the disturbance can be reduced. Further, the disturbance of the electric field distribution can also be reduced by using a high resistance instead of the insulator although the insulator is used as a material of the inner wall of the optical column 61 in the embodiments described above.

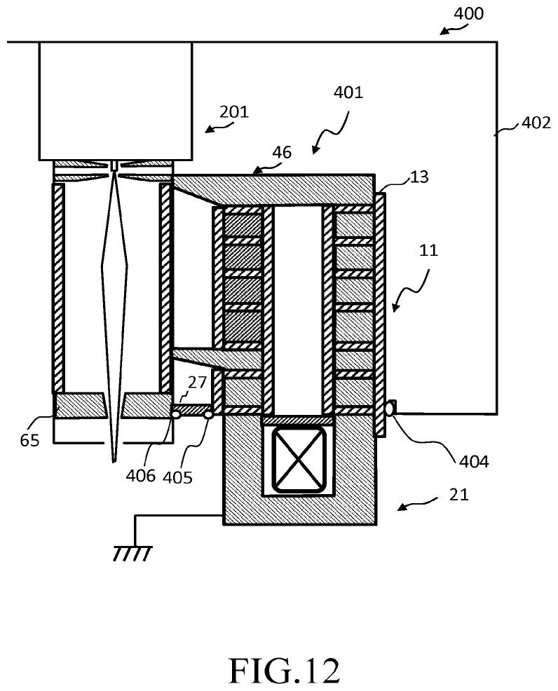

FIG. 12 is a sectional view showing an example of a configuration of an electron source mechanism according to another modified example of the first embodiment. In FIG. 12, in the sectional view of the electromagnetic lens 401, an illustration of the section of the opposite side across the electron gun 201 is omitted. Except for the portion close to the outlet of the electron beam 200 and the coil surrounding part 21 in the electron source mechanism 400, it is covered with a case body 402. The case body 402 is sealed by a sealing mechanism. It is preferable that the case body 42 is electrically grounded. In the example of FIG. 12, the outer peripheral wall 11 side is sealed with an O-ring 404. Further, the portion between the inner peripheral wall 16 and the non-magnetic material 27 is sealed with an O-ring 405. Further, the portion between the optical column 61 of the electron gun and the non-magnetic material 27 is sealed with an O-ring 406. Thereby, the space sealed by the electron gun 201, the electromagnetic lens 401, and the case body 402 is blocked from the outside. The sealed space outside the optical column 61 may be filled with insulating gas or insulating liquid. As the insulating liquid, for example, fluorinated inert liquid can be used. Here, the sealed space includes the space which is surrounded by the pole piece and in which neither a magnetic material nor an insulator is arranged. As shown in FIG. 12, preferably, the coil surrounding part 21 is disposed outside the sealed space. By this, the coil surrounding part 21 can be detached easily.

Next, an example of an electron beam irradiation apparatus in which the electron source mechanism 400 described above is installed will be explained.

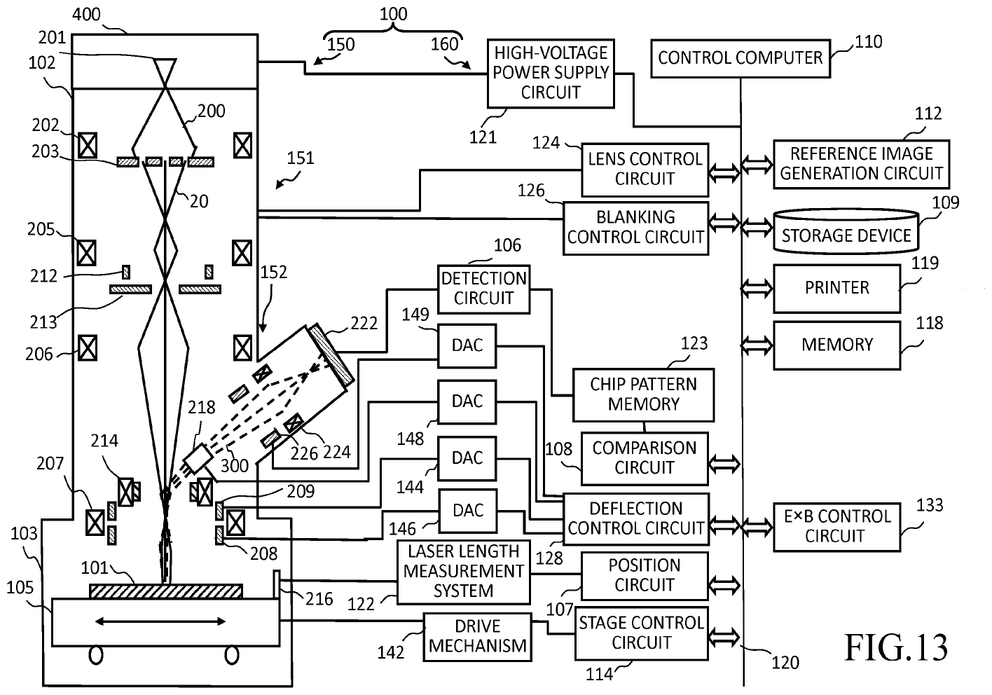

FIG. 13 is a diagram showing an example of a configuration of an inspection apparatus according to the first embodiment. In FIG. 13, an inspection apparatus 100 for inspecting a pattern formed on the substrate is an example of a multi-electron beam inspection apparatus. The inspection apparatus 100 includes an image acquisition mechanism 150 and a control system circuit 160. The image acquisition mechanism 150 includes the electron source mechanism 400, an electron beam column 102 (electron optical column), and an inspection chamber 103. The electron source mechanism 400 is disposed on the electron beam column 102. In the electron beam column 102, there are disposed an electromagnetic lens 202, a shaping aperture array substrate 203, an electromagnetic lens 205, a collective blanking deflector 212, a limiting aperture substrate 213, an electromagnetic lens 206, an electromagnetic lens 207 (objective lens), a two-stage deflector of a deflector 208 and a deflector 209, an E×B separator 214 (beam separator), a deflector 218, an electromagnetic lens 224, a deflector 226, and a multi-detector 222. Although FIG. 13 shows the case where the two-stage deflector composed of the deflectors 208 and 209 is disposed, a single stage deflector or a multi-stage deflector of three or more stages may also be used.

A primary electron optical system 151 (illumination optical system) is composed of the electromagnetic lens 202, the shaping aperture array substrate 203, the electromagnetic lens 205, the collective blanking deflector 212, the limiting aperture substrate 213, the electromagnetic lens 206, the electromagnetic lens 207 (objective lens), the deflector 208, and the deflector 209. A secondary electron optical system 152 (detection optical system) is composed of the electromagnetic lens 207, the ExB separator 214, the deflector 218, the deflector 226, and the electromagnetic lens 224.

In the inspection chamber 103, there is disposed a stage 105 movable at least in the x and y directions. On the stage 105, a substrate 101 (target object) to be inspected is placed. The substrate 101 may be an exposure mask substrate, or a semiconductor substrate such as a silicon wafer. In the case of the substrate 101 being a semiconductor substrate, a plurality of chip patterns (wafer dies) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed and transferred onto the semiconductor substrate a plurality of times, a plurality of chip patterns (wafer dies) are formed on the semiconductor substrate. The case of the substrate 101 being a semiconductor substrate is mainly described below. The substrate 101 is placed, with its pattern-forming surface facing upward, on the stage 105, for example. Further, on the stage 105, there is disposed a mirror 216 which reflects a laser beam for measuring a laser length emitted from a laser length measuring system 122 arranged outside the inspection chamber 103.

The multi-detector 222 is connected, at the outside of a secondary electron beam column 104, to a detection circuit 106. The detection circuit 106 is connected to a chip pattern memory 123.

In the control system circuit 160, a control computer 110 which controls the whole of the inspection apparatus 100 is connected, through a bus 120, to a high-voltage power supply circuit 121, a position circuit 107, a comparison circuit 108, a reference image generation circuit 112, a stage control circuit 114, a lens control circuit 124, a blanking control circuit 126, a deflection control circuit 128, an E×B control circuit 133, a storage device 109 such as a magnetic disk drive, a memory 118, and a printer 119. The deflection control circuit 128 is connected to DAC (digital-to-analog conversion) amplifiers 144, 146, 148 and 149. The DAC amplifier 146 is connected to the deflector 208, the DAC amplifier 144 is connected to the deflector 209, the DAC amplifier 148 is connected to the deflector 218, and the DAC amplifier 149 is connected to the deflector 226.

The chip pattern memory 123 is connected to the comparison circuit 108. The stage 105 is driven by a drive mechanism 142 under the control of the stage control circuit 114. In the drive mechanism 142, a drive system such as a three (x-, y-, and θ-) axis motor driving in the x, y, and θ directions in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measuring system 122, and supplied (transmitted) to the position circuit 107. Based on the principle of laser interferometry, the laser length measuring system 122 measures the position of the stage 105 by receiving a reflected light from the mirror 216. With respect to the stage coordinate system, the x, y, and θ directions of the primary coordinate system are set, for example, to a plane perpendicular to the optical axis of multiple primary electron beams 20.

The electromagnetic lenses 202, 205, 206, 207, and 224 are controlled by the lens control circuit 124. The E×B separator 214 is controlled by the E×B control circuit 133. The collective blanking deflector 212 is an electrostatic deflector composed of two or more electrodes (or poles), and each electrode is controlled by the blanking control circuit 126 through a DAC amplifier (not shown). The deflector 209 is an electrostatic deflector composed of four or more electrodes (or poles), and each electrode is controlled by the deflection control circuit 128 through the DAC amplifier 144. The deflector 208 is an electrostatic deflector composed of four or more electrodes (or poles), and each electrode is controlled by the deflection control circuit 128 through the DAC amplifier 146. The deflector 218 is an electrostatic deflector composed of four or more electrodes (or poles), and each electrode is controlled by the deflection control circuit 128 through the DAC amplifier 148. The deflector 226 is an electrostatic deflector composed of four or more electrodes (or poles), and each electrode is controlled by the deflection control circuit 128 through the DAC amplifier 149.

FIG. 13 shows configuration elements necessary for describing the first embodiment. Other configuration elements generally necessary for the inspection apparatus 100 may also be included therein.

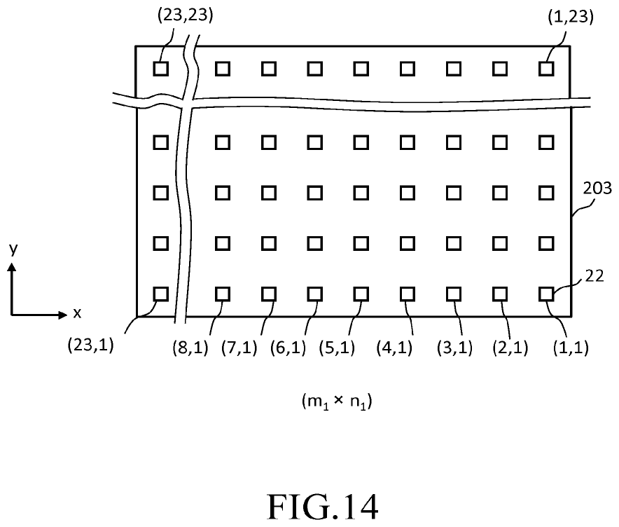

FIG. 14 is a conceptual diagram showing a configuration of a shaping aperture array substrate according to the first embodiment. As shown in FIG. 14, holes (openings) 22 of m₁ columns wide (width in the x direction) and n₁ rows long (length in the y direction), where each of m₁ and n₁ is an integer of 2 or more, are two-dimensionally formed in the x and y directions at a predetermined arrangement pitch in the shaping aperture array substrate 203. In the case of FIG. 14, 23×23 holes (openings) 22 are formed. Each of the holes 22 is a rectangle (including a square) having the same dimension, shape, and size. Alternatively, each of the holes 22 may be a circle with the same outer diameter. The multiple primary electron beams 20 are formed by letting portions of the electron beam 200 individually pass through a corresponding one of the plurality of holes 22. Next, operations of the image acquisition mechanism 150 in the case of acquiring a secondary electron image will be described below. In the primary electron optical system 151, the substrate 101 is irradiated with the multiple primary electron beams 20. Specifically, it operates as follows:

As described above, the electron beam 200 is emitted from the electron gun 201 of the electron source mechanism 400 under the control of the high-voltage power supply circuit 121.

The electron beam 200 emitted from the electron gun 201 (emission source) is refracted by the electromagnetic lens 202, and illuminates the whole of the shaping aperture array substrate 203. As shown in FIG. 14, a plurality of holes 22 (openings) are formed in the shaping aperture array substrate 203. The region including all the plurality of holes 22 is irradiated with the electron beam 200. The multiple primary electron beams 20 are formed by letting portions of the electron beam 200 applied to the positions of the plurality of holes 22 individually pass through a corresponding one of the plurality of holes 22 in the shaping aperture array substrate 203.

The formed multiple primary electron beams 20 are individually refracted by the electromagnetic lenses 205 and 206, and travel to the electromagnetic lens 207 (objective lens), while repeating forming an intermediate image and a crossover, passing through the E×B separator 214 arranged in the intermediate image plane of each beam of the multiple primary electron beams 20.

When the multiple primary electron beams 20 are incident on the electromagnetic lens 207 (objective lens), it focuses the multiple primary electron beams 20 to form an image on the substrate 101. The multiple primary electron beams 20 having been focused on the substrate 101 (target object) by the electromagnetic lens 207 are collectively deflected by the two-stage deflector of the deflectors 208 and 209 to irradiate respective beam irradiation positions on the substrate 101. In the case where all the multiple primary electron beams 20 are collectively deflected by the collective blanking deflector 212, they deviate from the hole in the center of the limiting aperture substrate 213 and are blocked by the limiting aperture substrate 213. In contrast, the multiple primary electron beams 20 which were not deflected by the collective blanking deflector 212 pass through the hole in the center of the limiting aperture substrate 213 as shown in FIG. 13. Blanking control is provided by On/Off of the collective blanking deflector 212, and thus On/Off of the multiple beams is collectively controlled. In this way, the limiting aperture substrate 213 blocks the multiple primary electron beams 20 which were deflected to be in an “Off state” by the collective blanking deflector 212. Then, the multiple primary electron beams 20 for image acquisition are formed by the beams having been made during a period from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300) including reflected electrons, each corresponding to each of the multiple primary electron beams 20, is emitted from the substrate 101 due to the irradiation with the multiple primary electron beams 20.

The multiple secondary electron beams 300 emitted from the substrate 101 pass through the electromagnetic lens 207, and travel to the E×B separator 214. The E×B separator 214 includes a plurality of, at least two, magnetic poles each having a coil, and a plurality of, at least two, electrodes (poles). For example, the E×B separator 214 includes four magnetic poles (electromagnetic deflection coils) whose phases are mutually shifted by 90°, and four electrodes (electrostatic deflection electrodes) whose phases are also mutually shifted by 90°. For example, by setting two opposing magnetic poles to be an N pole and an S pole, a directive magnetic field is generated by these plurality of magnetic poles. Also, for example, by applying electrical potentials V whose signs are opposite to each other to the two opposing electrodes, a directive electric field is generated by these plurality of electrodes. Specifically, the E×B separator 214 generates an electric field and a magnetic field to be orthogonal to each other in a plane perpendicular to the traveling direction of the center beam (i.e., trajectory center axis) of the multiple primary electron beams 20. The electric field exerts a force in a fixed direction regardless of the traveling direction of electrons. In contrast, the magnetic field exerts a force according to Fleming's left-hand rule. Therefore, the direction of the force acting on (applied to) electrons can be changed depending on the entering (or “traveling”) direction of electrons. With respect to the multiple primary electron beams 20 entering the E×B separator 214 from above, since the forces due to the electric field and the magnetic field cancel each other out, the beams 20 travel straight downward. In contrast, with respect to the multiple secondary electron beams 300 entering the E×B separator 214 from below, since both the forces due to the electric field and the magnetic field are exerted in the same direction, the beams 300 are bent obliquely upward, and separated from the trajectory of the multiple primary electron beams 20.

The multiple secondary electron beams 300 having been bent obliquely upward are further bent by the deflector 218, and travel to the electromagnetic lens 224. Then, the multiple secondary electron beams 300 travel to the multi-detector 222 while being refracted by the electromagnetic lens 224.

At the detection surface of the multi-detector 222, each beam of the multiple secondary electron beams 300 collides with a detection element corresponding to each of the multiple secondary electron beams 300, and therefore, electron amplification occurs and secondary electron image data is generated for each pixel. A strength signal detected by the multi-detector 222 is output to the detection circuit 106. A sub-irradiation region on the substrate 101, which is surrounded by the x-direction beam pitch and the y-direction beam pitch and in which the beam concerned itself is located, is irradiated and scanned with each primary electron beam.

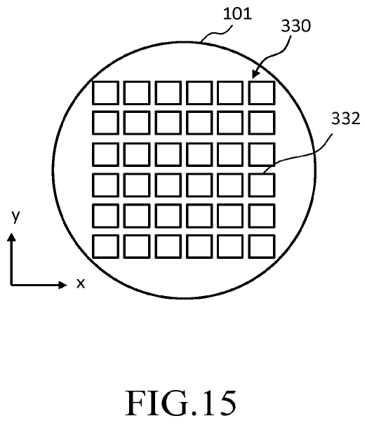

FIG. 15 is an illustration showing an example of a plurality of chip regions formed on a semiconductor substrate, according to the first embodiment. In FIG. 15, in the case of the substrate 101 being a semiconductor substrate (wafer), a plurality of chips (wafer dies) 332 are formed in a two-dimensional array in an inspection region 330 of the semiconductor substrate (wafer). A mask pattern for one chip formed on an exposure mask substrate is reduced to, for example, ¼, and exposed/transferred onto each chip 332 by an exposure device such as a stepper (not shown). The mask pattern for one chip is generally composed of a plurality of figure patterns.

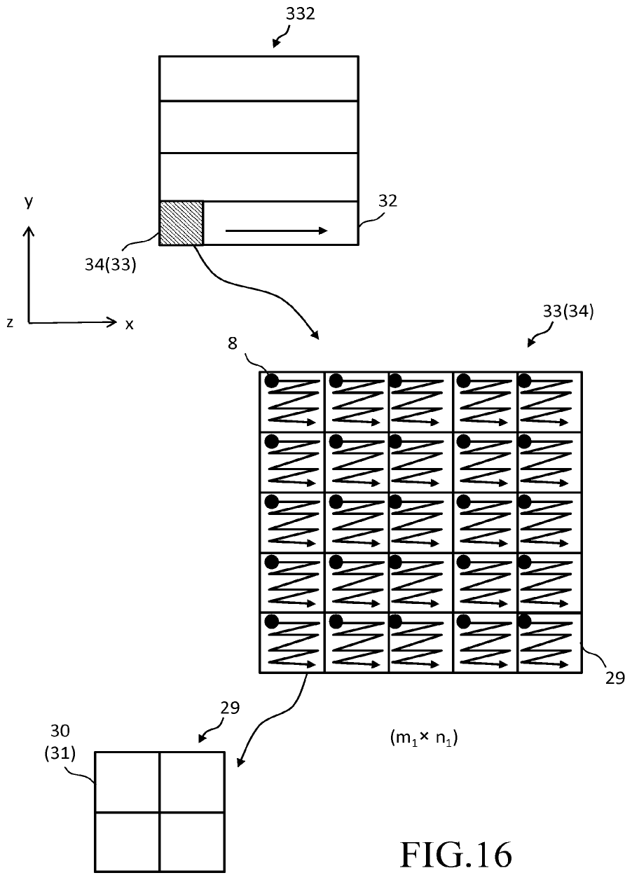

FIG. 16 is an illustration describing inspection processing according to the first embodiment. As shown in FIG. 16, the region of each chip 332 is divided, for example, in the y direction into a plurality of stripe regions 32 by a predetermined width. The scanning operation by the image acquisition mechanism 150 is carried out for each stripe region 32, for example. The operation of scanning the stripe region 32 advances relatively in the x direction while the stage 105 is moved in the −x direction, for example. Each stripe region 32 is divided in the longitudinal direction into a plurality of rectangular (including square) regions 33. Beam application to a target rectangular region 33 is achieved by collectively deflecting all the multiple primary electron beams 20 by the two-stage deflector of the deflectors 208 and 209.

The case of FIG. 16 shows the multiple primary electron beams 20 of 5 rows×5 columns, for example. The size of an irradiation region 34 which can be irradiated by one irradiation with the multiple primary electron beams 20 is defined by (x direction size obtained by multiplying an x-direction beam pitch of the multiple primary electron beams 20 on the substrate 101 by the number of beams in the x direction)×(y direction size obtained by multiplying a y-direction beam pitch of the multiple primary electron beams 20 on the substrate 101 by the number of beams in the y direction). The irradiation region 34 serves as a field of view of the multiple primary electron beams 20. A sub-irradiation region 29, which is surrounded by the x-direction beam pitch and the y-direction beam pitch and in which the beam concerned itself is located, is irradiated and scanned (scanning operation) with each primary electron beam 8 of the multiple primary electron beams 20. Each primary electron beam 8 is associated with any one of the sub-irradiation regions 29 which are different from each other. At the time of each shot, each primary electron beam 8 is applied to the same position in the associated sub-irradiation region 29. The primary electron beam 8 is moved in the sub-irradiation region 29 by collective deflection of all the multiple primary electron beams 20 by the two-stage deflector of the deflectors 208 and 209. The position of the multiple secondary electron beams 300 emitted by collectively deflecting all the multiple primary electron beams 20 by the deflectors 208 and 209 also changes. Since, if as it is, each of the multiple secondary electron beams 300 does not enter a corresponding detection element of the multi-detector 222, the deflection amount of the deflected multiple primary electron beams 20 is swung back by collectively deflecting all the multiple secondary electron beams 300 by the deflector 226. Thereby, it becomes possible to make each of the multiple secondary electron beams 300 enter a corresponding detection element of the multi-detector 222. By repeating this operation, the inside of one sub-irradiation region 29 is irradiated, in order, with one primary electron beam 8.

Preferably, the width of each stripe region 32 is set to be the same as the size in the y direction of the irradiation region 34, or to be the size reduced by the width of the scanning margin. In the cases of FIG. 16, the irradiation region 34 and the rectangular region 33 are of the same size. However, it is not limited thereto. The irradiation region 34 may be smaller than the rectangular region 33, or larger than it. Using each primary electron beam 8 of the multiple primary electron beams 20, the sub-irradiation region 29 in which the primary electron beam 8 concerned itself is located is irradiated with the primary electron beam 8 concerned, and scanned by collective deflection of all the multiple primary electron beams 20 by the deflectors 208 and 209. Then, when scanning of one sub-irradiation region 29 is completed, the irradiation position is moved to an adjacent rectangular region 33 in the same stripe region 32 by collectively deflecting all the multiple primary electron beams 20 by the two-stage deflector of the deflectors 208 and 209. By repeating this operation, the stripe region 32 is irradiated in order. After completing scanning of one stripe region 32, the irradiation region 34 is moved to the next stripe region 32 by moving the stage 105 and/or by collectively deflecting all the multiple primary electron beams 20 by the deflector 208. As described above, by irradiation with each primary electron beam 8, the scanning operation per sub-irradiation region 29 and acquisition of a secondary electron image are performed. By combining these secondary electron images of respective sub-irradiation regions 29, a secondary electron image of the rectangular region 33, a secondary electron image of the stripe region 32, or a secondary electron image of the chip 332 is configured. When an image comparison is actually performed, the sub-irradiation region 29 in each rectangular region 33 is further divided into a plurality of frame regions 30, and then, a comparison is performed with respect to a frame image 31 of each frame region 30. FIG. 16 shows the case of dividing the sub-irradiation region 29 which is scanned with one primary electron beam 8 into four frame regions 30 by halving it in the x and y directions.

As described above, the image acquisition mechanism 150 proceeds with a scanning operation per stripe region 32. The multiple secondary electron beams 300 emitted from the substrate 101 due to the irradiation with the multiple primary electron beams 20 is detected by the multi-detector 222. A reflected electron may be included in the detected multiple secondary electron beams 300. Alternatively, it is also acceptable that a reflected electron is separated during moving in the secondary electron optical system 152 not to reach the multi-detector 222. Detected data (measured image data: secondary electron image data: inspection image data) on the secondary electron of each pixel in each sub-irradiation region 29, detected by the multi-detector 222, is output to the detection circuit 106 in order of measurement. In the detection circuit 106, the detected data in analog form is converted into digital data by an A-D converter (not shown), and stored in the chip pattern memory 123. Then, acquired measured image data is transmitted to the comparison circuit 108, together with information on each position from the position circuit 107.

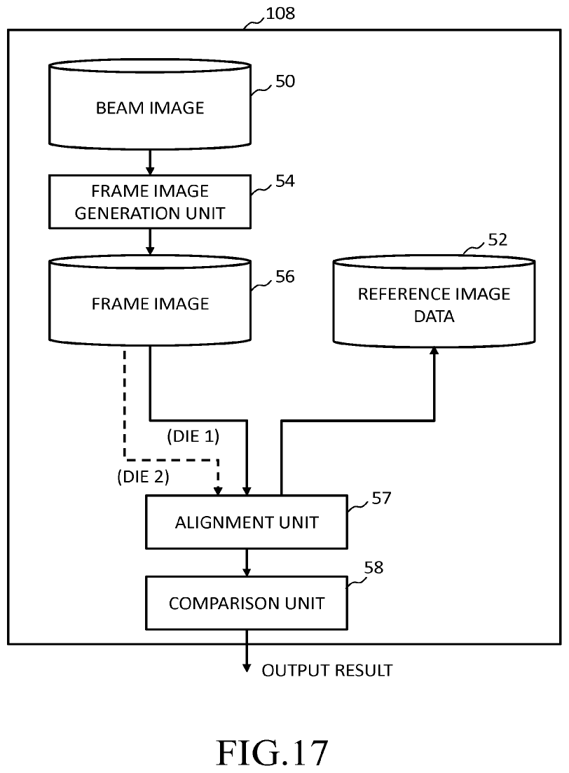

FIG. 17 is a diagram showing an example of an internal configuration of a comparison circuit according to the first embodiment. In FIG. 17, storage devices 50, 52 and 56 such as magnetic disk drives, a frame image generation unit 54, an alignment unit 57, and a comparison unit 58 are arranged in the comparison circuit 108. Each of the “units” such as the frame image generation unit 54, the alignment unit 57 and the comparison unit 58 includes processing circuitry. The processing circuitry includes an electric circuit, a computer, a processor, a circuit board, a quantum circuit, a semiconductor device, or the like. Further, common processing circuitry (same processing circuitry), or different processing circuitry (separate processing circuitry) may be used for each of the “units”. Input data required in the frame image generation unit 54, the alignment unit 57 and the comparison unit 58, or a calculated result is stored in a memory (not shown) or in the memory 118 each time.

Measured image data (beam image) transmitted into the comparison circuit 108 is stored in the storage device 50.

The frame image generation unit 54 generates the frame image 31 of each of a plurality of frame regions 30 obtained by further dividing image data of the sub-irradiation region 29 acquired by scanning with each primary electron beam 8. The frame region 30 is used as a unit region of an inspection image to be inspected. In order to prevent missing an image, it is preferable that the margin region of each frame region 30 overlaps with each other. The generated frame image 31 is stored in the storage device 56.

In a reference image generation step, the reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data of binary or multiple values.

As described above, basic figures defined by the design pattern data are, for example, rectangles (including squares) and triangles. For example, there is stored figure data defining the shape, size, position, and the like of each pattern figure by using information, such as coordinates (x, y) of the reference position of the figure, lengths of sides of the figure, and a figure code serving as an identifier for identifying the figure type such as rectangles and triangles.

When design pattern data used as the figure data is input to the reference image generation circuit 112, the data is developed/expanded into data for each figure. Then, with respect to each figure data, the figure code, the FIG. dimensions, and the like indicating the figure shape of each figure data are interpreted. The reference image generation circuit 112 develops each figure data to design pattern image data in binary or multiple values as a pattern to be arranged in squares in units of grids of predetermined quantization dimensions, and outputs the developed data. In other words, the reference image generation circuit 112 reads design data, calculates the occupancy of a figure in the design pattern, for each square region obtained by virtually dividing the inspection region into squares in units of predetermined dimensions, and outputs n-bit occupancy data. For example, it is preferable to set one square as one pixel. Assuming that one pixel has a resolution of 1/2⁸(=1/256), the occupancy rate in each pixel is calculated by allocating sub-regions, each having 1/256 resolution, which correspond to the region of a figure arranged in the pixel. Then, it is generated as occupancy rate data of 8 bits. Such squares (inspection pixels) can be commensurate with pixels of measured data.

Next, using a predetermined filter function, the reference image generation circuit 112 performs filtering processing on design image data of a design pattern which is image data of a figure. Thereby, it becomes possible to match/fit the design image data being design side image data, whose image intensity (gray scale level) is represented by digital values, with image generation characteristics obtained by irradiation with the multiple primary electron beams 20. Image data for each pixel of a generated reference image is output to the comparison circuit 108. The reference image data transmitted into the comparison circuit 108 is stored in the storage device 52.

In a comparison step, first, the alignment unit 57 reads the frame image 31 serving as an inspection image, and a reference image corresponding to the frame image 31, and provides alignment between both the images, based on units of sub-pixels smaller than pixels. For example, the alignment can be performed by a least-square method.

Then, the comparison unit 58 compares at least a portion of an acquired secondary electron image with a predetermined image. Here, a frame image obtained by further dividing the image of the sub-irradiation region 29 acquired for each beam is used. The comparison unit 58 compares, for each pixel, the frame image 31 and a reference image. The comparison unit 58 compares them, for each pixel, based on predetermined determination conditions in order to determine whether there is a defect such as a shape defect. For example, if a difference in gray scale level for each pixel is larger than a determination threshold Th, it is determined that there is a defect. Then, the comparison result is output. It may be output to the storage device 109 or the memory 118, or alternatively, output from the printer 119.

In the above examples, the die-to-database inspection has been described. However, it is not limited thereto. A die-to-die inspection may be performed. In the case of the die-to-die inspection, alignment and comparison having been described above are carried out between the frame image 31 (die 1) to be inspected and another frame image 31 (die 2) (another example of a reference image) in which there is formed the same pattern as that of the frame image 31 to be inspected.

As described above, according to the first embodiment, it is possible to arrange the pole piece 46 to be close to the acceleration space 68 (an electric field space) of a high potential difference whose absolute value is high while suppressing an electric field disturbance.

### Second Embodiment

In a second embodiment, a configuration of the electromagnetic lens 401 differing from that of the first embodiment will be described. The contents of the second embodiment are the same as those of the first embodiment except what is specifically described below.

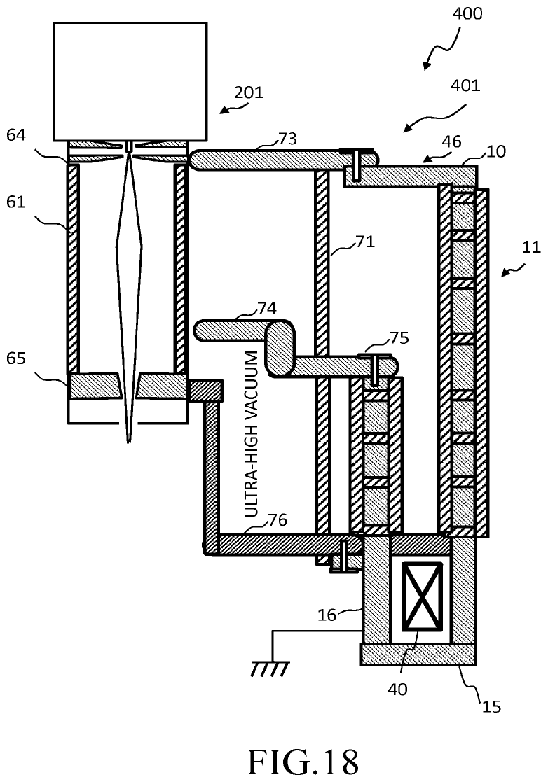

FIG. 18 is a sectional view showing an example of a configuration of an electron source mechanism according to the second embodiment. In FIG. 18, in the sectional view of the electromagnetic lens 401, an illustration of the section of the opposite side across the electron gun 201 is omitted. In the example of FIG. 18, the outer peripheral wall 11 is lengthened to increase the creepage distance between the high voltage portion and the ground potential portion. Thereby, the possibility of occurrence of a creeping discharge can be further reduced. The same applies to the inner peripheral wall 16. Due to this, however, the height positions of at least the flange 42 and the non-magnetic material 27 result in being changed. Then, according to the second embodiment, the distance between the pole piece 46 and the electron gun 201 is lengthened in order to adjust the deviation of the height position. Specifically, configuration is performed as follows: An upper wall 73 made of a conductive magnetic material is attached to the inner peripheral side of the upper wall 10 with a fixing screw 75. The upper wall 73 is electrically connected to the extractor 64. In the example of FIG. 18, the upper wall 73 is connected in contact with the extractor 64. In other words, the upper wall 73 (second upper wall) is arranged at the inner peripheral side than the upper wall 10 (first upper wall), and connects the upper wall 10 and the electron source. Further, a flange 74 of a conductive magnetic material is attached to the gap side end (upper end) of the inner peripheral wall 16 with the fixing screw 75. The flange 74 is connected to the side surface of the case body 61 at the same height position as that where the flange 42 is connected to the side surface of the case body 61. In other words, the flange 74 is connected to the upper end of the inner peripheral wall 16, and connects the upper end of the inner peripheral wall 16 and the electron source, at the height position shifted to the upper wall 73 side than the upper end of the inner peripheral wall 16 of the electron source. The inner peripheral wall 16 and the anode electrode 65 are connected through the conductive non-magnetic material 76 instead of the non-magnetic material 27. The non-magnetic material 76 is, similarly to the non-magnetic material 27, connected to the position of the grounded magnetic material 17 in the inner peripheral wall 16.

A tubular insulator 71 separates between the pole piece 46 and the electron gun 201. The insulator 71 is connected, at the inner peripheral side than the fixing screw 75, to the upper wall 73, the flange 74, and the non-magnetic material 76. Thereby, the region can be divided into an ultra-high vacuum region at the inside of the insulator 71 and a region of atmospheric air or insulating fluid at the outside of the insulator 71.

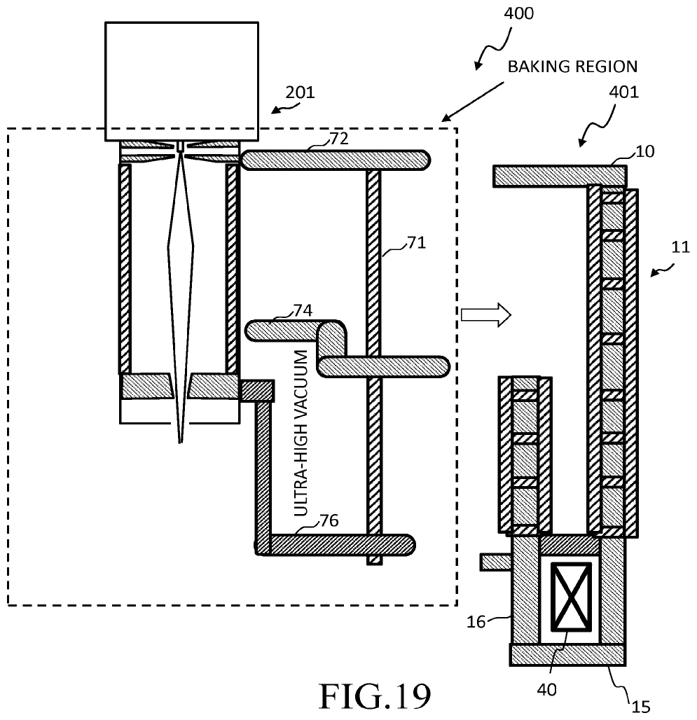

FIG. 19 is an illustration for explaining an example of a separation mechanism of an electromagnetic lens according to the second embodiment. In the second embodiment, the pole piece 46 is formed to be detachable from the electron gun 201 in the state where the upper wall 73 and the flange 74 are left at the electron gun 201 side. As shown in FIG. 19, when baking the electron gun 201, the fixing screw 75 is unscrewed to separate the electromagnetic lens 401 from the electron gun 201. For example, in FIG. 18, the screw fixing the upper wall 73 and the upper wall 10 to each other, the screw fixing the non-magnetic material 76 and the inner peripheral wall 16 to each other, and the fixing screw 75 fixing the flange 74 and the inner peripheral wall 16 to each other are unscrewed. Then, the pole piece 46 is lowered downward without moving the upper wall 73 and the flange 74. In the case of FIG. 19, although the pole piece 46 is shown at the outer peripheral side in order to intelligibly depict the separation (detachment), it is sufficient just to perform thermal insulation at the time of baking. Therefore, what is necessary is only to lower the pole piece 46 downward, and unnecessary to completely pull it out. In the first embodiment, the case has been described where baking is conducted to the pole piece 46, except the coil surrounding part 21, together with the electron gun 201. In contrast, in the case of FIG. 19, since the electromagnetic lens 401 itself is detached, it becomes unnecessary to conduct baking to the pole piece 46. Therefore, it is unnecessary to cool the pole piece 46. Since cooling the pole piece 46 which takes a long time can be omitted, the cool time for the whole of the electron source mechanism 400 after baking can be shortened. Other configurations are the same as those of FIG. 1. Further, each of the modified examples of the first embodiment described referring to FIGS. 8, 9, 11, and 12 can be applied to the second embodiment.

### Third Embodiment

Although the first embodiment describes the mechanism for detaching the coil surrounding part 21 of the pole piece 46, it is not limited thereto. In a third embodiment, a configuration of the electromagnetic lens 401 differing from that of the first embodiment will be described. The contents of the third embodiment are the same as those of the first embodiment except what is specifically described below.

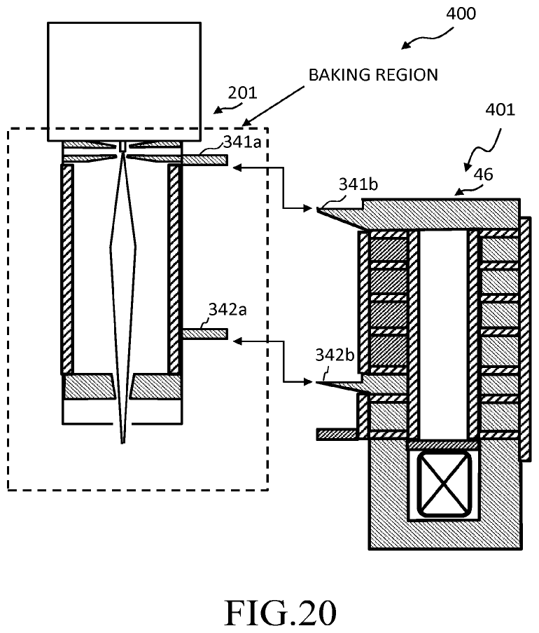

FIG. 20 is a sectional view showing an example of a configuration of an electron source mechanism according to the third embodiment. In FIG. 20, in the sectional view of the electromagnetic lens 401, an illustration of the section of the opposite side across the electron gun 201 is omitted. FIG. shows a configuration where the flange 41 (an example of the first flange) of the upper wall 10 and the flange 42 (an example of the second flange) of the inner peripheral wall 16 are formed to be detachable individually. The flange 41 is configured by separably combining an upper portion 341a which remains at the electron gun side, and a lower portion 341b which is at the upper wall 10 side. Similarly, the flange 42 is configured by separably combining an upper portion 342a which remains at the electron gun side, and a lower portion 342b which is at the upper wall 10 side. The upper portion 341a of the flange 41 and the upper portion 342a of the flange 42 are connected to the electron gun 201 which is arranged surrounded by the electromagnetic lens 401.

According to the third embodiment, the pole piece 46 is formed to be detachable from the electron gun 201 by separating the upper portion 341a of the flange 41 from the lower portion 341b, and the upper portion 342a of the flange 42 from the lower portion 342b. When baking the electron gun 201, the upper portion 341a of the flange 41 is separated from the lower portion 341b, and the upper portion 342a of the flange 42 is separated from the lower portion 342b. Thereby, the electromagnetic lens 401 is separated from the electron gun 201. Similarly to the case of FIG. 19, a screw (not shown) fixing the upper portion 341a and the lower portion 341b to each other, and a screw (not shown) fixing the upper portion 342a and the lower portion 342b to each other are unscrewed. Since it is sufficient just to perform thermal insulation at the time of baking, what is necessary is only to lower the pole piece 46 downward, and unnecessary to completely pull it out. Further, it is also preferable that, for example, a slit is formed in the upper portion 341a, another slit is formed in the lower portion 342b, and, after lowering the pole piece 46 downward, the pole piece 46 is rotated such that the upper portion 341a passes through the slit of the lower portion 342b and the lower portion 342b passes through the slit of the upper portion 341a so as to pull the pole piece 46 out downward. In the first embodiment, the case has been described where baking is conducted to the pole piece 46, except the coil surrounding part 21, together with the electron gun 201. In contrast, in the case of FIG. 20, since the electromagnetic lens 401 itself is detached, it becomes unnecessary to conduct baking to the pole piece 46. Therefore, the cool time for the whole of the electron source mechanism 400 after baking can be shortened. Other configuration is the same as that of FIG. 1. Further, each of the modified examples of the first embodiment described referring to FIGS. 8, 9, 11, and 12 can be applied to the third embodiment.

### Fourth Embodiment

Each embodiment mentioned above describes an electromagnetic lens that generates one magnetic field distribution, but it is not limited thereto. A fourth embodiment describes an electromagnetic lens that generates a plurality of magnetic field distributions. The contents of the fourth embodiment are the same as those of the first embodiment except what is specifically described below.

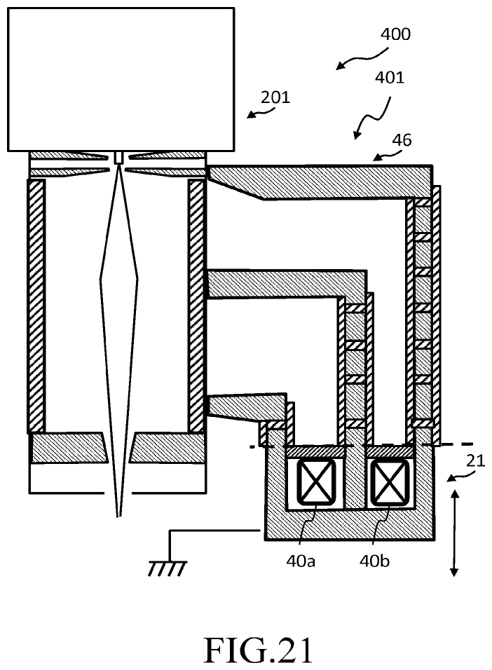

FIG. 21 is a sectional view showing an example of a configuration of an electron source mechanism according to the fourth embodiment. In FIG. 21, in the sectional view of the electromagnetic lens 401, an illustration of the section of the opposite side across the electron gun 201 is omitted. Two coils 40a and 40b are disposed in FIG. 21. The coils 40a and 40b are separated from each other by a magnetic material. The first-stage electromagnetic lens is formed by the coil 40b and the pole piece which is formed by the upper wall, outer peripheral wall, lower wall, and inner peripheral wall surrounding the coil 40b. The second-stage electromagnetic lens is formed by the coil 40a and the pole piece which is formed by the upper wall, outer peripheral wall, lower wall, and inner peripheral wall surrounding the coil 40a. A flange connected to the optical column of the electron gun 201 is arranged at the upper end of the inner peripheral wall of the second-stage electromagnetic coil. The outer peripheral wall of the second-stage electromagnetic lens also serves as the inner peripheral wall of the first-stage electromagnetic lens. With respect to the pole pieces 46 of the first-stage and second-stage electromagnetic coils, their inner and outer peripheral walls upper than the two coils 40a and 40b have a laminated structure of a magnetic material and an insulator.

The upper wall of the first-stage electromagnetic lens is connected to the extractor 64. The flange of the inner peripheral wall of the second-stage electromagnetic lens is connected to the optical column at a position a little higher than the anode electrode 65. The upper wall of the second-stage electromagnetic lens is connected to the optical column at a height position between the above height positions.

The magnetic field generated by the first-stage electromagnetic lens is emitted from the gap between the upper walls of the first-stage and second-stage electromagnetic lenses. The magnetic field generated by the second-stage electromagnetic lens is emitted from the gap between the upper wall of the second-stage electromagnetic lens, and the flange of the inner peripheral wall of the second-stage electromagnetic lens. Therefore, two magnetic field distributions having different height positions are generated. Thereby, it becomes possible to variably control the height position of the peak position of the combined magnetic field distribution by variably adjusting magnetic field strengths of the first-stage and second-stage electromagnetic lenses. In the pole pieces 46 of the first-stage and second-stage electromagnetic coils, the coil surrounding part 21 which individually surrounds the coil 40a and the coil 40b is formed to be detachable. Thereby, when performing baking, the two coils 40a and 40b can be separated from the baking region. Other configuration is the same as that of FIG. 1 or FIG. 10. Further, each of the modified examples of the first embodiment described referring to FIGS. 8, 9, 11, and 12 can be applied to the fourth embodiment.

The two stage electromagnetic lens is described in the case of FIG. 21, but a three or more stage electromagnetic lens may also be used.

### Fifth Embodiment

Each embodiment mentioned above describes the case where the portion at the inner peripheral side of the upper wall 10 extends to form the flange 41, but it is not limited thereto.

FIG. 22 is a sectional view showing an example of a configuration of an electron source mechanism according to a fifth embodiment. In FIG. 22, in the sectional view of the electromagnetic lens 401, an illustration of the section of the opposite side across the electron gun 201 is omitted. As described above, a gap for emitting a magnetic field is formed between the opposite facing surfaces of the upper and lower parts of the inner peripheral wall 16, or between the opposite facing surfaces of the upper wall 10 and the inner peripheral wall 16. In the example of FIG. 22, the inner peripheral wall 16 of the pole piece 46 is divided into the upper part (part A) and the lower part (part B). Then, a gap for emitting a magnetic field is formed between the opposite facing surfaces of the upper and lower parts of the inner peripheral wall 16. The opposite surfaces of the upper and lower parts of the inner peripheral wall 16, which form a gap, are insulated electrically. In the case of FIG. 22, the surfaces forming the gap have flanges 41 and 42 which extend to the inner peripheral side. The flange 41 is integrated, using the same magnetic material, with the upper part of the inner peripheral wall 16.

The end of the flange 41, being the inner peripheral side end of the upper part of the inner peripheral wall 16, is electrically connected to the extractor 64 of the electron gun 201 arranged surrounded by the electromagnetic lens 401. By arranging the upper wall 10 at a position higher than the height position of the extractor 64, since the outer peripheral wall 11 of the pole piece 46 can be lengthened, the creepage distance can be increased. Accordingly, the possibility of occurrence of a creeping discharge can be reduced. Other configuration is the same as that of FIG. 1 or FIG. 10. Further, each of the modified examples of the first embodiment described referring to FIGS. 8, 9, 11, and 12 can be applied to the fifth embodiment.

In the above description, each “ . . . circuit” includes processing circuitry. The processing circuitry includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). Programs for causing a processor, etc. to execute processing may be stored in a recording medium, such as a magnetic disk drive, magnetic tape drive, FD, ROM (Read Only Memory) or the like. For example, the position circuit 107, the comparison circuit 108, the reference image generation circuit 112, the stage control circuit 114, the lens control circuit 124, the blanking control circuit 126, the deflection control circuit 128, and the E×B control circuit 133 may be formed by at least one processing circuit described above. For example, processing in these circuits may be carried out by the control computer 110.

Embodiments have been explained referring to specific examples described above. However, the present invention is not limited to these specific examples. In the examples described above, for example, the electromagnetic lens 401 is arranged to surround the electron gun 201, but it is not limited thereto. The electromagnetic lens 401 may be arranged at a position other than that surrounding the electron gun 201. For example, it is also preferable to apply an electromagnetic lens having the same configuration as that of the electromagnetic lens 401 to at least one of the electromagnetic lenses 205, 206, 207, and 224.

While the apparatus configuration, control method, and others not directly necessary for explaining the present invention are not described, some or all of them can be appropriately selected and used on a case-by-case basis when needed. For example, although the above embodiments describe the case of generating multiple beams, the contents of the above embodiments can also be applied to an apparatus using a single beam.

Further, any electromagnetic lens and electron source mechanism that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electromagnetic lens comprising:
a coil, and
a pole piece configured to include an upper wall, a lower wall, an outer peripheral wall, and an inner peripheral wall which are formed using a conductive magnetic material, to surround the coil by the upper wall, the lower wall, the outer peripheral wall and the inner peripheral wall, one of opposite facing surfaces of an upper part and a lower part of the inner peripheral wall and opposite facing surfaces of the upper wall and the inner peripheral wall being insulated electrically, the outer peripheral wall including a laminated structure where a magnetic material and an insulator are alternately laminated in a direction of a central axis of a trajectory of a passing electron beam, and to be covered at least the laminated structure of the outer peripheral wall with an insulator.

2. The electromagnetic lens according to claim 1, wherein, in the pole piece, a portion where the coil is disposed is grounded.

3. The electromagnetic lens according to claim 1, wherein one of an inner peripheral side end of the upper part of the inner peripheral wall and an inner peripheral side end of the upper wall is electrically connected to an electrode of an electron source disposed surrounded by the electromagnetic lens.

4. The electromagnetic lens according to claim 3, wherein
the electrode of the electron source is formed by a magnetic material, and magnetically connected to one of the inner peripheral side end of the upper part of the inner peripheral wall and the inner peripheral side end of the upper wall, and
the electromagnetic lens generates a lens magnetic field in an acceleration space in the electron source.

5. The electromagnetic lens according to claim 1 further comprising:
at least one voltage dividing resistance configured to be arranged between adjacent magnetic materials in the laminated structure.

6. The electromagnetic lens according to claim 2, wherein the portion where the coil is disposed is formed by the lower wall, a portion of the outer peripheral wall, and a portion of the inner peripheral wall.

7. The electromagnetic lens according to claim 1, wherein the pole piece includes a laminated structure which is arranged at one of a position between the opposite facing surfaces of the upper part and the lower part of the inner peripheral wall, and a position between the opposite facing surfaces of the upper wall and the inner peripheral wall, and in which a conductive non-magnetic material and an insulator are alternately laminated.

8. The electromagnetic lens according to claim 1, wherein a portion where the coil is disposed is formed to be detachable from other portions of the pole piece.

9. The electromagnetic lens according to claim 1, wherein
the upper wall has a first flange extending to an inner peripheral side than the inner peripheral wall, and
the inner peripheral wall has a second flange, at an upper end, extending to the inner peripheral side than other portions of the inner peripheral wall.

10. The electromagnetic lens according to claim 1 wherein the upper wall is a first upper wall, further comprising:
a second upper wall configured to be arranged at an inner peripheral side than the first upper wall, and to connect the first upper wall and an electron source disposed surrounded by the electromagnetic lens, and
a flange configured to be connected to an upper end of the inner peripheral wall, and to connect the upper end of the inner peripheral wall and the electron source, at a height position shifted to a second upper wall side than the upper end of the inner peripheral wall of the electron source.

11. The electromagnetic lens according to claim 10 further comprising:
a tubular insulator configured to separate between the electron source and the pole piece.

12. The electromagnetic lens according to claim 10, wherein the pole piece is formed to be detachable from the electron source in a state where the second upper wall and the flange are left at an electron source side.

13. The electromagnetic lens according to claim 9, wherein
the first flange is configured by separably combining an upper portion and a lower portion,
the second flange is configured by separably combining an upper portion and a lower portion,
the upper portion of the first flange and the upper portion of the second flange are connected to an electron source disposed surrounded by the electromagnetic lens, and
the pole piece is formed to be detachable from the electron source by separating the upper portion of the first flange from the lower portion of the first flange, and the upper portion of the second flange from the lower portion of the second flange.

14. An electron source mechanism comprising:
an electromagnetic lens including
a coil, and
a pole piece configured to include an upper wall, a lower wall, an outer peripheral wall and an inner peripheral wall which are formed using a conductive magnetic material, to surround the coil by the upper wall, the lower wall, the outer peripheral wall and the inner peripheral wall, one of opposite facing surfaces of an upper part and a lower part of the inner peripheral wall and opposite facing surfaces of the upper wall and the inner peripheral wall being insulated electrically, the outer peripheral wall having a laminated structure where a magnetic material and an insulator are alternately laminated in a direction of a central axis of a trajectory of a passing electron beam, and to be covered at least the laminated structure of the outer peripheral wall with an insulator, and
an electron source configured to be disposed, where an electron beam acceleration space to which a lens action is applied is arranged so as to be surrounded by the electromagnetic lens, emit an electron beam, and accelerate the electron beam in a space surrounded by the electromagnetic lens.
